(19) United States
(12) Patent Application Publication
(10) Pub. No.: US 2017/0154955 A1
(43) Pub. Date: Jun. 1, 2017

(54) SEMICONDUCTOR DEVICE

(71) Applicant: Mitsubishi Electric Corporation, Tokyo (JP)

(72) Inventors: Tatsuo HARADA, Tokyo (JP); Shigeto HONDA, Tokyo (JP); Akito NISHII, Tokyo (JP); Ze CHEN, Tokyo (JP)

(73) Assignee: Mitsubishi Electric Corporation, Tokyo (JP)

(21) Appl. No.: 15/173,749

(22) Filed: Jun. 6, 2016

(30) Foreign Application Priority Data
Nov. 26, 2015 (JP) 2015-230229

(51) Int. Cl. H01L 29/06

(52) U.S. Cl. CPC H01L 29/0615

(57) ABSTRACT

A semiconductor device includes: a semiconductor substrate; a device region on the semiconductor substrate; a planar edge termination region on the semiconductor substrate to surround the device region; and a passivation film covering the edge termination region, wherein the passivation film includes a semi-insulating film directly contacting the semiconductor substrate.

### BACKGROUND OF THE INVENTION

Field

The present invention relates to a semiconductor device including a planar edge termination region.

Background

In conventional semiconductor devices, an insulating film has been used as a passivation film for covering a planar edge termination region (e.g., see Japanese Patent Application Publication No. 2010-003762).

When a semiconductor device is reversely biased, a high electric field region is formed, and electrons pulled by the high electric field become hot carriers. In particular, in an edge termination region, since the edge termination region is floating, the hot carriers generated are injected into an insulating film which is a conventional passivation film, and part of the hot carriers are likely to be trapped into the insulating film. An increase in space charge in the insulating film tends to increase interface states and the positive charge density at an interface between the insulating film and a semiconductor substrate. Accordingly, the extension of a depletion layer generated at the interface between the insulating film and the semiconductor substrate in reverse bias is reduced, and electric field concentration occurs at only a part of a surface of the semiconductor substrate to extremely increase a leakage current and may cause a reduction in breakdown voltage. To reduce breakdown voltage variation in a reliability test in which reverse bias is continuously applied, electric field concentration needs to be reduced by elongating the edge termination region to reduce the electric field. Conventionally, this problem has been solved by widening the edge termination region. Accordingly, an ineffective region increases to inhibit semiconductor device miniaturization.

### SUMMARY

The present invention has been accomplished to solve the above-described problems, and an object of the present invention is to provide a semiconductor device in which a leakage current and a size can be reduced.

According to the present invention, a semiconductor device includes: a semiconductor substrate; a device region on the semiconductor substrate; a planar edge termination region on the semiconductor substrate to surround the device region; and a passivation film covering the edge termination region, wherein the passivation film includes a semi-insulating film directly contacting the semiconductor substrate.

In the present invention, the semi-insulating film directly contacting the semiconductor substrate is used as the passivation film covering the edge termination region. Thus, hot carriers generated in reverse bias are not taken into the semi-insulating film, and the formation of space charge can be inhibited. Accordingly, interface states and the positive charge density between the passivation film and the semiconductor substrate can be kept low. Thus, when the semiconductor device using the planar edge termination region is reversely biased, depletion on the surface of the semiconductor substrate is not hindered, and the electric field can be prevented from extremely increasing. As a result, a leakage current can be reduced, and breakdown voltage stability can be improved. This eliminates the necessity of elongating the edge termination region. Accordingly, the size of the semiconductor device can be reduced.

Other and further objects, features and advantages of the invention appear more fully from the following description.

### BRIEF DESCRIPTION OF DRAWINGS

FIG. 1 is a plan view showing a semiconductor device according to an embodiment of the present invention.

FIG. 2 is a cross-sectional view taken along line I-II of FIG. 1.

FIG. 3 is a view showing a result of comparing actually measured leakage currents of the diode of the present embodiment and a conventional diode.

### DESCRIPTION OF EMBODIMENTS

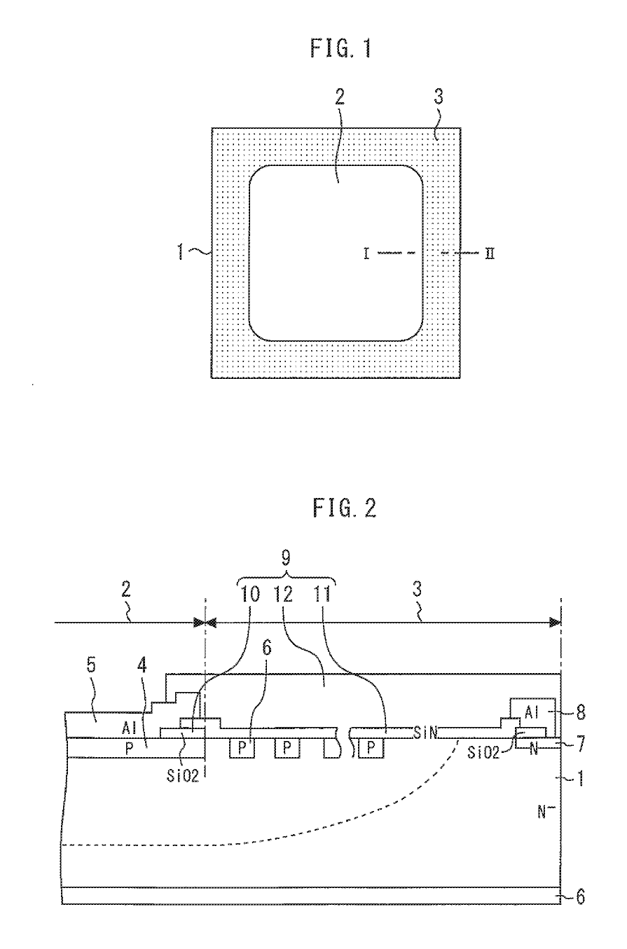

FIG. 1 is a plan view showing a semiconductor device according to an embodiment of the present invention. A device region 2 is formed in a central portion of a semiconductor substrate 1. A planar edge termination region 3 is formed on the semiconductor substrate 1 to surround the device region 2.

FIG. 2 is a cross-sectional view taken along line I-II of FIG. 1. In the device region 2, a P-type anode layer 4 is formed on a front side of the N⁻-type semiconductor substrate 1. An anode electrode 5 made of Al is formed on the P-type anode layer 4. A cathode electrode 6 is formed on a back side of the semiconductor substrate 1. The device region 2 functions as a diode.

In the edge termination region 3, a plurality of ring-shaped P-type ring layers 6 are formed on the front side of the semiconductor substrate 1 to surround the P-type anode layer 4. A channel stopper 7 made of an N-type diffusion layer is formed to surround the P-type ring layers 6. An Al electrode 8 is connected to the channel stopper 7. When the semiconductor device is reversely biased, a depletion layer (broken line in FIG. 2) is formed in the semiconductor substrate 1. Along with this, an electric field is generated in the device region 2 and part of the edge termination region 3.

A passivation film 9 is integrally formed to cover part of the device region 2 and the edge termination region 3. The passivation film 9 is a multilayer film including a SiO₂ film 10 covering an outer end portion of the P-type anode layer 4 and a portion of the channel stopper 7, a semi-insulating film 11 which directly contacts the semiconductor substrate 1 and which is made of semi-insulating SiN, and an insulating film 12 formed on the foregoing. With an applied voltage of 10 V, the resistance value of the semi-insulating film 11 is 10⁷ to 10¹¹ [Ω/mm²].

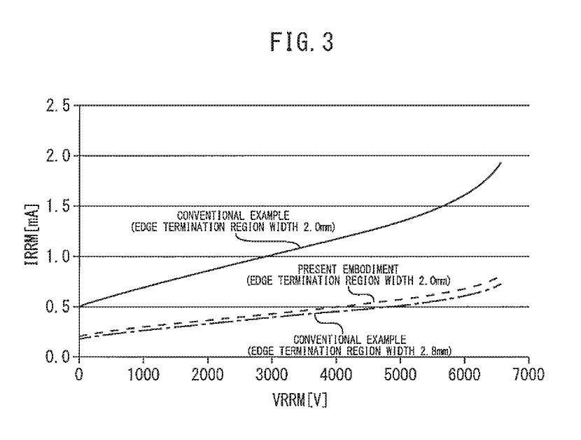

FIG. 3 is a view showing a result of comparing actually measured leakage currents of the diode of the present embodiment and a conventional diode. In the conventional example, an insulating film is used as a passivation film. VRRM refers to reversely applied voltage between anode and cathode, and IRRM refers to leakage current. Using VRRM=6500 V as a rated voltage, leakage currents were compared. In the diode of the present embodiment, the leakage current is 0.8 mA. In the conventional example having the same edge termination region width as the present embodiment, the leakage current extremely increases to 1.9 mA. In the conventional example, to make the leakage current approximately equal to that of the present embodiment, the width of the edge termination region needs to be increased by a factor of approximately 1.4.

As described above, in the present embodiment, the semi-insulating film 11 is used as the passivation film 9 covering the edge termination region 3. The semi-insulating film 11 directly contacts the semiconductor substrate 1 with no insulating film such as the SiO₂ film 10 interposed therebetween. Thus, hot carriers generated in reverse bias are not taken into the semi-insulating film 11, and the formation of space charge can be inhibited. Accordingly, interface states and the positive charge density between the passivation film 9 and the semiconductor substrate 1 can be kept low. Thus, when the semiconductor device using the planar edge termination region 3 is reversely biased, depletion on the surface of the semiconductor substrate 1 is not hindered, and the electric field can be prevented from extremely increasing. As a result, a leakage current can be reduced, and breakdown voltage stability can be improved. This eliminates the necessity of elongating the edge termination region 3. Accordingly, the size of the semiconductor device can be reduced.

Moreover, the edge termination region 3 has an FLR (Field Limiting Ring) structure or an LNFLR (Linearly-narrowed Field Limiting Ring) structure including the plurality of ring-shaped P-type ring layers 6. Thus, voltage sharing among the plurality of P-type ring layers 6 can be achieved. Therefore, the electric field on the surface of the semiconductor substrate 1 can be prevented from extremely increasing. Meanwhile, in the case of an RESURF structure or a ULD structure, spaced ring layers are not arranged, and potential sharing among ring layers cannot be achieved. Accordingly, the electric field tends to extremely increase at an end portion of the depletion layer. Even if a semi-insulating film is used as a passivation film, a leakage current cannot be reduced. Thus, the edge termination region can be narrowed to a certain extent but, to narrow the edge termination region more than necessary, breakdown voltage variation needs to be reduced in a reliability test. Accordingly, a leakage current can be further reduced by using an FLR structure or an LNFLR structure and the semi-insulating film 11 in combination.

The semi-insulating film 11 is preferably a plasma CVD film. In the case of a plasma CVD film, a semi-insulating film can be relatively easily formed.

The insulating film 12 is preferably a high-K film. In the case of a high-K film, the film thickness of the insulating film 12 can be increased in accordance with the permittivity thereof without decreasing the capacitance in the passivation film 9.

It should be noted that though a diode is formed in the device region 2 in the semiconductor devices according to embodiments 1 and 2, the present invention is not limited to this. For example, a semiconductor device such as an IGBT or a power MOSFET may be formed.

Moreover, the semiconductor substrate 1 is not limited to being made of silicon, and may be made of a wide band gap semiconductor having a wider band gap than silicon. Examples of the wide band gap semiconductor are, for example, silicon carbide, gallium nitride-based materials, and diamond. A power semiconductor device made of such a wide band gap semiconductor has a high breakdown voltage and a high allowable current density; and can therefore be miniaturized. By using the miniaturized device, a semiconductor module into which the device is incorporated can also be miniaturized. Further, since the heat resistance of the device is high, radiation fins of a heat sink can be miniaturized, and a water-cooled portion can be changed to an air-cooled portion. Accordingly, the semiconductor module can he further miniaturized. Moreover, by virtue of small power loss in the device and high efficiency thereof, the efficiency of the semiconductor module can be improved.

Obviously many modifications and variations of the present invention are possible in the light of the above teachings. It is therefore to he understood that within the scope of the appended claims the invention may be practiced otherwise than as specifically described.

The entire disclosure of Japanese Patent Application No. 2015-230229, filed on Nov. 26, 2015 including specification, claims, drawings and summary, on which the Convention priority of the present application is based, is incorporated herein by reference in its entirety.

1. A semiconductor device comprising:
a semiconductor substrate;
a device region on the semiconductor substrate;
a planar edge termination region on the semiconductor substrate to surround the device region; and
a passivation film covering the edge termination region,
wherein the passivation film includes a semi-insulating film directly contacting the semiconductor substrate.

2. The semiconductor device of claim 1, wherein a resistance value of the semi-insulating film is 10⁷ to 10¹¹ [Ωmm²].

3. The semiconductor device of claim 1, wherein the edge termination region has an FLR (Field Limiting Ring) structure or an LNFLR (Linearly-narrowed Field Limiting Ring) structure including a plurality of ring-shaped ring layers.

4. The semiconductor device of claim 1, wherein the semi-insulating film is a plasma CVD film.

5. (canceled)
